(19) United States
(12) Patent Application Publication
(10) Pub. No.: US 2018/0120110 A1
(43) Pub. Date: May 3, 2018

(54) MEMS LINK MECHANISM USED FOR GYROSCOPE

(71) Applicant: SHIN SUNG C&T CO., LTD., Seoul (KR)

(72) Inventors: Ci Moo Song, Yongin-si (KR); Keun Jung Youn, Dong-gu (KR); Jeong Sik Kang, Seoul (KR); Yong Kook Kim, Seoul (KR); Seung Ho Han, Asan-si (KR); Hyun Ju Song, Seoul (KR)

(73) Assignee: SHIN SUNG C&T CO., LTD., Seoul (KR)

(21) Appl. No.: 15/856,616

(22) Filed: Dec. 28, 2017

Related U.S. Application Data
(63) Continuation of application No. PCT/KR2016/006876, filed on Jun. 28, 2016.

(30) Foreign Application Priority Data
Jul. 1, 2015 (KR) 10-2015-0094029

(51) Int. Cl. G01C 19/5747; G01C 19/5621; G01C 19/5712; B81B 7/02; G01C 19/5769

(52) U.S. Cl. CPC G01C 19/5747; G01C 19/5621; G01C 19/5769; B81B 7/02; G01C 19/5712

(57) ABSTRACT

Provided is a MEMS anti-phase link mechanism for ensuring anti-phase movements of two axisymmetric mass body units forming a sensor mass body, in a MEMS-based gyroscope including: a frame disposed to be parallel to a bottom wafer substrate; the sensor mass body in which displacement is sensed by Coriolis force when a movement in an excitation direction and an external angular velocity are input to the frame; and at least one sensing electrode which senses the displacement of the sensor mass body. The MEMS anti-phase link mechanism includes at least two anchor connecting parts connected to an immovable central anchor; and at least two link arms which are connected to the at least two anchor connecting parts, and are connected to the two mass body units in a 180-degree rotational symmetry with each other on the basis of the center of the MEMS anti-phase link mechanism.

### CROSS-REFERENCE

This application is a continuation application of international application PCT/KR2016/006876, filed on Jun. 28, 2016, now pending, which claims foreign priority from Korean Patent Application No. 10-2015-0094029 filed on Jul. 1, 2015 in the Korean Intellectual Property Office, the disclosure of each document is incorporated herein by reference in their entirety.

### TECHNICAL FIELD

The present invention relates to a MEMS gyroscope, and more particularly, to a MEMS link mechanism used for a MEMS gyroscope having a plurality of mass bodies axisymmetrically arranged.

### BACKGROUND ART

MEMS (Micro Electro Mechanical Systems) is a technique for providing mechanical and electrical components, using a semiconductor process. A representative example of an element using the MEMS technique is a MEMS gyroscope which measures the angular velocity. The gyroscope measures a Coriolis force generated when a rotational angular velocity is applied to an object moving at a predetermined velocity, thereby measuring the angular velocity. At this time, the Coriolis force is proportional to a cross product of the moving velocity and the rotational angular velocity caused by the external force.

Further, in order to sense the generated Coriolis force, the gyroscope is provided with mass body which vibrates inside the gyroscope. Normally, a direction in which a mass body in the gyroscope is driven is referred to as an excitation direction, a direction in which the rotational angular velocity is input to the gyroscope is referred to as an input direction, and a direction in which the Coriolis force generated in the mass body is sensed is referred to as a sensing direction.

The excitation direction, the input direction, and the sensing direction are set in directions orthogonal to each other on the space. Normally, in the gyroscope using the MEMS technique, the coordinate axes are set in the three directions including two directions (a horizontal direction or an x-y direction) which are parallel to the plane formed by a bottom wafer substrate and perpendicular to each other, and a direction (a vertical direction or a z-direction) perpendicular to a plate surface of the substrate.

Therefore, the gyroscope is divided into an x-axis or (y-axis) gyroscope and a z-axis gyroscope. The x-axis gyroscope is a gyroscope in which the input direction is the horizontal direction, and the y-axis gyroscope is based on the vertical axis with the x-axis gyroscope on the plane. However, in the principle aspect, the y-axis gyroscope is substantially the same as the x-axis gyroscope. Thus, the x-axis and y-axis gyroscopes are collectively referred to as the x-y axis gyroscope. Meanwhile, in order to measure the angular velocity applied in the vertical direction using the z-type gyroscope, the excitation needs to be performed in one axial direction on the plane, and the sensing needs to be performed in the direction perpendicular to the one axis on the plane. Accordingly, all the excitation electrodes and the sensing electrodes are located on the same bottom wafer.

FIG. 1 is a schematic diagram illustrating a z-axis MEMS gyroscope having 1 degree of freedom (DOF) horizontal excitation and 1 degree of freedom horizontal sensing function, and FIG. 2 is a schematic diagram illustrating an x-y axis MEMS gyroscope having 1 degree of freedom horizontal excitation and 1 degree of freedom vertical sensing function. Here, a frame 2 and a sensor 4 are provided inside the gyro wafer, the sensor 4 is connected to the frame 2 by a spring (kdx) and an attenuator (cdx), and the sensor mass body (ms) may be connected to the sensor 4 by a spring (ksy or ksz) and an attenuator (csy or csz).

The vibrating sensor mass body (ms) is disposed inside the MEMS gyroscope. When the angular velocity is applied around an axis (z or y) perpendicular to the excitation direction x from the outside, a Coriolis force (Fc=2 mΩ×ωA sin ωt) acts in a third direction (y or z) perpendicular to the plane formed by the sensor mass body, and the magnitude of the operation of the sensor mass body varied by the Coriolis force is sensed. Here, ms is a mass of the sensor mass body, ω is the external angular velocity, ω=(2πf) is an excitation frequency of the sensor mass body, A is the driving amplitude of the sensor, and t is time.

On the other hand, in the conventional x-y axis MEMS gyroscope as illustrated in FIG. 2, the excitation direction and the sensing direction may be reversely configured. In other words, the excitation is performed in the z-direction, and the movement in the x-direction due to the Coriolis force is sensed. FIG. 3 illustrates an example of such an x-y axis MEMS gyroscope of the type of the z-direction excitation and the x-direction sensing. In particular, here, a tuning fork type is used in which two mass bodies are arranged in the x-direction axisymmetry within the frame of the conventional x-y axis gyroscope.

In x-y axis MEMS gyroscope of FIG. 3, the excitation direction of the frame 2 is performed in the z-direction. At this time, an excitation type in which the overall frame translates in the z-direction is also possible. However, in particular, in such a tuning fork type, since it is necessary to make the two mass bodies (ms1 and ms2) move in the opposite directions, the frame 2 may be excited to have a seesaw movement in the z-direction. At this time, due to the characteristics of the seesaw movement, the excitation forces acting on the mass bodies (ms1 and ms2) are opposite to each other.

Under such an excitation force, when an external rotation in the y-axis direction acts on the x-y axis MEMS gyroscope, a left mass body (ms1) which is supported by the attenuators (cs1 and cs1′) in the x-axis direction, and a left mass body (ms2) which is supported by the attenuators ((cs2 and cs2′)) and the springs (ks2 and ks2′) in the y-axis direction vibrate in the x-axis direction. In particular, since the directions of the excitation forces acting on the mass bodies (ms1 and ms2) are opposite to each other, the two mass bodies (ms1 and ms2) and the right mass body (ms2) have the displacement of anti-phase with each other. Thus, in addition to the structural symmetry of the MEMS gyroscope, if the movement of the sensor mass body also has the symmetry, an error due to a manufacturing process or an error caused by external noise may be offset by its symmetry.

As described above, since an ultra-small precision device such as the MEMS gyroscope is sensitive to the external noise or the manufacturing process errors, the toughness or stability of the system is a very important consideration factor. However, in this way, such an effect can be achieved to some extent by axisymmetrically disposing the two mass bodies in the MEMS gyroscope.

However, even though the MEMS gyroscope is designed with the purpose of providing the perfect anti-phase movement in the excitation or sensing of the sensor mass body, the two sensor mass bodies may not be actually excited with a perfect anti-phase by the excitation electrode due to various internal or external factors. Even if the MEMS gyroscope is excited with the perfect anti-phase, it is not easy to ensure the perfect anti-phase movement in the sensing mode.

Therefore, in the MEMS gyroscopes having two axisymmetrically arranged mass bodies, it is necessary to devise a structure which not only is easy to manufacture, but also can ensure the perfect anti-phase in the excitation mode or sensing mode.

### DISCLOSURE

### Technical Problems

An object of the present invention is to provide a MEMS structure capable of ensuring the perfect anti-phase in the excitation mode or sensing mode, in a MEMS gyroscope having the two axisymmetrically arranged mass bodies.

Another aspect of the present invention is to provide a MEMS gyroscope including a structure capable of ensuring such a perfect anti-phase without causing additional manufacturing processes or costs.

The objects of the present invention are not limited to those mentioned above and another object which has not been mentioned can be clearly understood by those skilled in the art from the description below.

### Technical Solutions

According to an aspect of the present invention, there is provided a MEMS anti-phase link mechanism for ensuring anti-phase movements of two axisymmetric mass body units forming a sensor mass body, in a MEMS-based gyroscope including: a frame disposed to be parallel to a bottom wafer substrate; the sensor mass body in which displacement is sensed by Coriolis force when a movement in an excitation direction and an external angular velocity are input to the frame; and at least one sensing electrode which senses the displacement of the sensor mass body. The MEMS anti-phase link mechanism includes at least two anchor connecting parts connected to an immovable central anchor; and at least two link arms which are connected to the at least two anchor connecting parts, and are connected to each of the two mass body units in a 180-degree rotational symmetry with each other on the basis of the center of the MEMS anti-phase link mechanism.

### Advantageous Effects

According to the MEMS link mechanism used in the MEMS gyroscope having two axisymmetrical mass bodies, since the perfect anti-phase is ensured in at least one mode of the excitation mode or sensing mode, it is possible to provide fine process errors or toughness to external noise.

Since the provision of the toughness is provided using a simple MEMS link structure that can be manufactured in an integrated gyro wafer processing process, there is an advantage that no special additional process or additional cost occurs.

### BRIEF DESCRIPTION OF DRAWINGS

FIG. 1 is a schematic diagram illustrating a conventional z-axis MEMS gyroscope having a 1 degree of freedom (DOF) horizontal excitation and 1 degree of freedom horizontal sensing function.

FIG. 2 is a schematic diagram illustrating a conventional x-axis (or y-axis) MEMS gyroscope having 1 degree of freedom horizontal excitation and 1 degree of freedom vertical sensing function.

FIG. 3 is a schematic diagram illustrating a conventional x-y axis MEMS gyroscope of a z-direction excitation and x-direction sensing type of the tuning fork type.

FIG. 4 is a schematic diagram illustrating an x-y axis MEMS gyroscope of z-direction excitation and x-direction sensing type of the tuning fork type according to an embodiment of the present invention.

FIG. 5 is a diagram illustrating reactive force acting on both sensor mass bodies when two rotationally symmetrical arms are connected to a central anchor.

FIG. 6 is a diagram illustrating the reactive force acting on the two sensor mass bodies when two arms are connected to a closed curve structure without a central anchor.

FIG. 7 is a diagram illustrating an anti-phase link mechanism according to an embodiment of the present invention.

FIG. 8 is a diagram illustrating the principle of operation of the x-y axis gyroscope of 1 degree of freedom vertical excitation and 2 degree of freedom horizontal sensing mode according to an embodiment of the present invention.

FIG. 9 is a diagram illustrating a frequency response curve of the x-y axis gyroscope of 1 degree of freedom vertical excitation and 2 degree of freedom horizontal sensing mode as illustrated in FIG. 8.

FIG. 10 is a graph illustrating the frequency response curve of the conventional z-axis gyroscope of 1 degree of freedom horizontal excitation and 1 degree of freedom horizontal sensing mode or the conventional x-y axis gyroscope of the 1 degree of freedom horizontal sensing and 1 degree of freedom vertical sensing mode.

FIG. 11 is a 1 degree of freedom mathematical model of a gyro frame and a torsional support spring that are vertically excited in the x-y axis gyroscope according to an embodiment of the present invention.

FIG. 12 is a diagram schematically illustrating a frame for disposing a link mechanism in which two mass body unit units enable an anti-phase sensing mode operation according to another embodiment of the present invention.

FIG. 13 is a diagram illustrating the structure of the x-y axis gyroscope vertically excited and horizontally sensed in which the anti-phase link mechanisms is disposed on the x-y plane of FIG. 12.

FIG. 14 is a plane view schematically illustrating an n or p-electrode on the front surface of the bottom wafer, a dummy metal pad on the front surface of the bottom wafer, a silicon penetration electrode, and a sealing wall of the bottom wafer in the x-y axis gyroscope according to the embodiment of FIG. 13.

FIG. 15 is a diagram schematically illustrating a cross section taken along line B-B′ in the x-y axis gyroscope of FIG. 14.

FIG. 16 is a diagram illustrating an example in which an anti-phase link mechanism is used in the x-y axis MEMS gyroscope having 1 degree of freedom excitation and 1 degree of freedom sensing mode according to an embodiment of the present invention.

FIG. 17 is a schematic diagram for explaining a driving principle of the z-axis gyroscope of horizontal excitation and horizontal sensing type according to an embodiment of the present invention.

FIG. 18 is a diagram illustrating an anti-phase link mechanism used for the z-axis gyroscope of FIG. 17 according to an embodiment of the present invention.

FIG. 19 is a diagram illustrating an anti-phase link mechanism used for the z-axis gyroscope of FIG. 17 according to another embodiment of the present invention.

FIG. 20 is a diagram illustrating the structure of a z-axis gyroscope horizontally excited and horizontally sensed on the x-y plane according to an embodiment of the present invention.

FIG. 21 is a diagram schematically illustrating a cross section taken along line A-A′ of the z-axis MEMS gyroscope of FIG. 20.

FIG. 22 is a plan view schematically illustrating a large number of anchors connected to the bottom wafer, the silicon penetration electrode and the sealing wall of the bottom wafer in the z-axis gyroscope according to the embodiment of FIG. 20.

FIG. 23 is a diagram schematically illustrating a cross section taken along line B-B′ of the x-y axis gyroscope of FIG. 22.

FIGS. 24, 25, 26, & 27 are diagrams illustrating the MEMS anti-phase link mechanism according to various embodiments of the present invention.

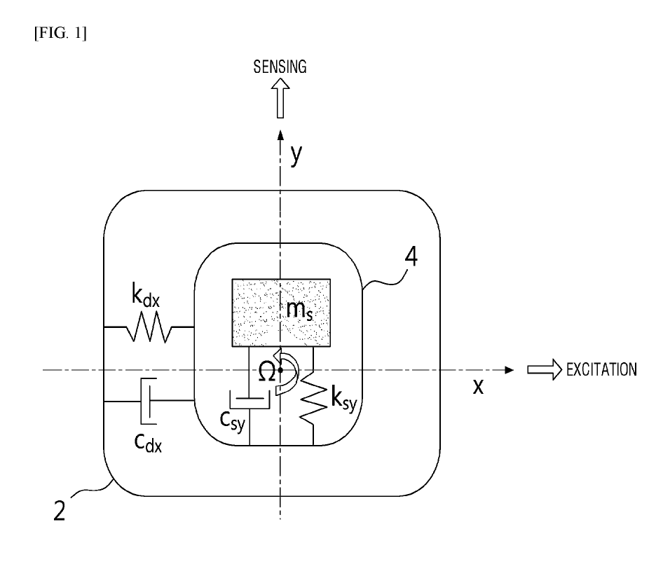

### BEST MODES FOR CARRYING OUT THE INVENTION

Advantages and features of the present invention and methods of accomplishing them will become apparent with reference to the embodiments described in detail below with reference to the accompanying drawings. It should be understood, however, that the present invention is not limited to the embodiments disclosed below but may be embodied in various different forms, the embodiments are merely provided to make the disclosure of the present invention perfect, and to perfectly inform the invention to a person having ordinary knowledge in the technical field to which the invention belongs, and the present invention is only defined by the scope of the claims. The same reference numerals refer to the same constituent elements throughout the specification.

Further, the embodiments described herein will be described with reference to a perspective view, a cross-sectional view, a side view, and/or a schematic view, which are ideal illustrations of the present invention. Therefore, the form of the illustration can be modified by manufacturing technique and/or tolerance and the like. Therefore, the embodiments of the present invention are not limited to the specific forms illustrated, but also include a change in the form generated according to the manufacturing process. Also, in each drawing illustrated in the present invention, each constituent element may be slightly enlarged or reduced in view of the convenience of explanation.

Hereinafter, an embodiment of the present invention will be described in detail with reference to the accompanying drawings.

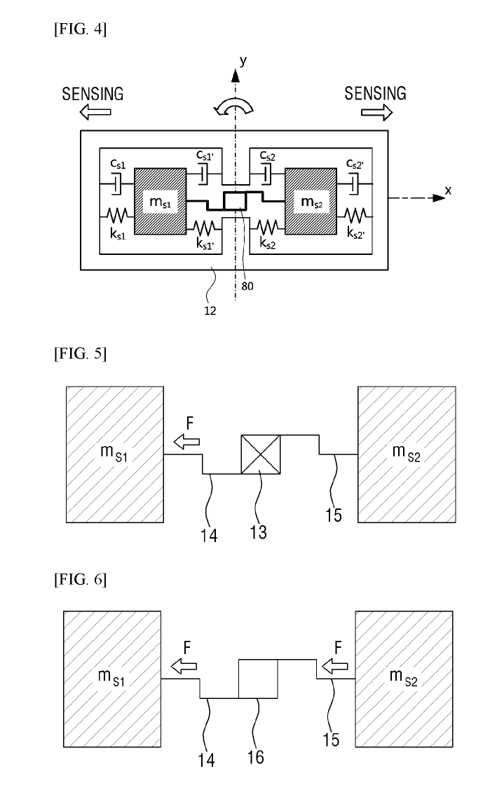

FIG. 4 is a diagram illustrating an example in which an anti-phase link mechanism 80 is applied to the tuning fork type x-y axis MEMS gyroscope. As in the case of FIG. 3, the frame 12 is excited in the z-direction in FIG. 4. In particular, in order to make two mass bodies (ms1 and ms2) have movements in the opposite directions, the frame 12 is excited to have a seesaw movement in the z-direction (a direction perpendicular to the drawing) around the y-axis. Therefore, due to the characteristics of the seesaw movement, the excitation forces acting on the mass bodies (ms1 and ms2) are opposite to each other.

Under the excitation forces, when an external rotation in the y-axis direction acts on the x-y axis MEMS gyroscope, a left mass body (ms1) supported by the attenuator (cs1 and cs1′) and the springs (ks1 and ks1′) in the x-axis direction, and a right mass body (ms2) supported by the attenuators (cs2 and cs2′) and the springs (ks2 and ks2′) in the y-axis direction vibrate in the x-axis direction. In particular, since the directions of the excitation force acting on the two mass bodies (ms1 and ms2) are opposite to each other, the left mass body (ms1) and the right mass body (ms2) have displacement of the mutually anti-phases.

In this way, even in the x-y axis MEMS gyroscope of FIG. 4, basically the excitation of the anti-phase is performed on each of the mass bodies (ms1 and ms2) as in FIG. 3, and the movement in the sensing direction may be measured with the anti-phase, accordingly. However, even if the MEMS gyroscope tries to provide the perfect anti-phase movement in the excitation or sensing of the sensor mass body, both sensor mass bodies may not be actually excited with the perfect anti-phase due to various internal or external factors. Even if the perfect anti-phase excitation is possible, the perfect anti-phase movement is not ensured in the sensing mode. Therefore, in order to ensure the perfect anti-phase movement (in the excitation mode or the sensing mode) of the tuning fork type MEMS gyroscope, an anti-phase link mechanism 80 for directly connecting between the two mass bodies (ms1 and ms2) is directly coupled in FIG. 4. To this end, as illustrated in FIG. 3, unlike the configuration in which the two mass bodies (ms1 and ms2) are arranged in the separated regions within the frame, except for the portion for connecting the springs or the attenuators, the two regions are caused to substantially communicate with each other in order to directly couple the anti-phase link mechanism.

Further, in order to secure the perfect anti-phase of the anti-phase link mechanism in FIG. 4, it is required to design the link mechanism such that forces acting on one arm (a portion connected to ms1) and the other arm (a portion connected to ms2) of the anti-phase link mechanism are perfectly opposite to each other. Therefore, it is desirable that the anti-phase link mechanism has a rotationally symmetric structure on the basis of the central part from the viewpoint of form.

However, as illustrated in FIG. 5, assuming a form in which the two arms 14 and 15 that are rotationally symmetric on the basis of the central anchor 13 are connected to the two mass bodies (ms1 and ms2), respectively, even if the mass body (ms1) exerts a force F on the first arm 14, it has no influence on the second arm 15 and the second mass body (ms2). That is, only by simply disposing the two arms 14 and 15 rotationally symmetrically on the basis of the central anchor 13, the anti-phases of the two mass bodies (ms1 and ms2) are not ensured.

On the other hand, as illustrated in FIG. 6, assuming a form in which the two arms 14 and 15 are connected to the closed curve structure 16 without a central anchor, when the first mass body (ms1) exerts the force F on the first arm 14, since the force F in the same direction is also exerted on the second arm 15, the second mass body (ms2) finally has the same phase as the first mass body (ml) rather than the anti-phase.

In this way, referring to FIGS. 5 and 6, in order to ensure the anti-phase movement of the two mass bodies (ms1 and ms2), only a condition in which the links are simply rotationally symmetric is not enough, and the additional consideration for the structure design is necessary.

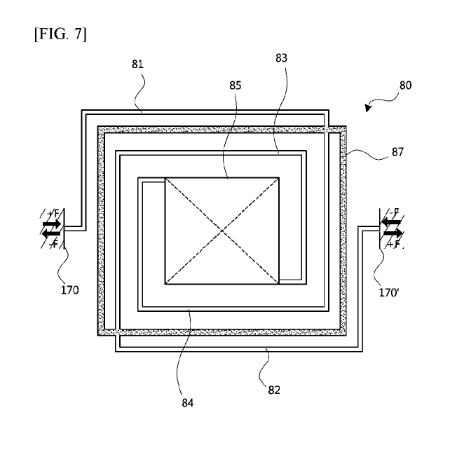

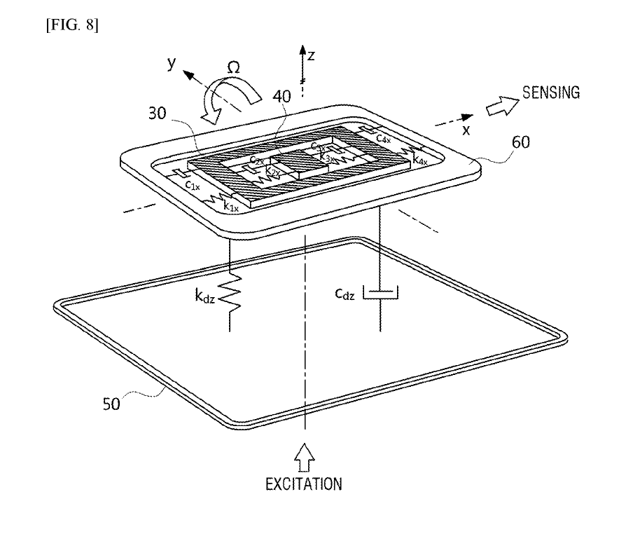

In consideration of this point, the anti-phase link mechanism 80 according to an embodiment of the present invention may be configured as illustrated in FIG. 7. The anti-phase link mechanism 80 includes two anchor connecting parts 83 and 84 connected to a central anchor 85 that does not move with respect to the frame 160, and two link arms 81 and 82 that are connected to the two anchor connecting parts 83 and 84 and connected to each of the two mass body units in the manner of being rotationally symmetric with each other by 180 degrees on the basis of the center of the anti-phase link mechanism 80. These link arms 81 and 82 preferably have at least three bending points (cusp) from the point connected to the torsional stiffness support part 87 of the closed curve shape to the point connected to the two mass body units 170 and 170′.

Further, a torsional stiffness support part 87 is included. The torsional stiffness support part 87 imparts the torsional stiffness to the anti-phase link mechanism 80, and is formed by the closed curve at least passing through the point on which the two anchor connecting parts 83 and 84 meet the two link arms 81 and 82. The torsional stiffness support part 87 also has a function of geometrically connecting a first structure including the first anchor connection 83 and the first link arm 81 with a second structure including the second anchor connection 84 and the second link arm 82, together with the torsional stiffness support part. If there is no such a torsional stiffness support part 87, since the first structure and the second structure are connected only to the central anchor 85 with no connection point, the anti-phase force does not occur.

In FIG. 7, if +F is added to the distal end of the first link arm 81, due to the 180 degree rotationally symmetric structure of the anti-phase link mechanism 80, the exactly reactive force of −F occurs at the distal end of the second link arm 82. Likewise, if −F is applied to the distal end of the first link arm 81, the exactly reactive force of +F occurs at the distal end of the second link arm 82. Even if the perfect anti-phase is not ensured in the movement of the two sensor mass body units only by the anti-phase excitation, since the two sensor mass body units have the perfect anti-phase movement due to the structural characteristics of such an anti-phase link mechanism, it is possible to enjoy the advantage capable of offsetting and removing the noise component that may occur at the sensing electrode.

Hereinafter, a specific example in which the anti-phase link mechanism 80 is applied to the x-y axis MEMS gyroscope will be described.

FIG. 8 is a schematic diagram for explaining the x-y axis gyroscope driving principle of the vertical excitation and horizontal sensing form according to an embodiment of the present invention. Referring to FIG. 8, under the condition that the rotation ω in the y-axis direction is applied to the bottom wafer 50 and the frame 60, when the sensor mass bodies 30 and 40 are excited in the z-axis direction, the amplitude of the sensor mass bodies 30 and 40 is sensed in the x-axis direction by the Coriolis force. Here, the sensor mass bodies 30 and 40 include an external mass body 30, and an internal mass body 40 perfectly surrounded by the external mass body 30. It is possible to perform modelling such that the two mass bodies 30 and 40 are connected by the springs (k2x and k3x) and the attenuators (c2x and c3x) arranged in the x-direction, and the frame 60 and the external mass body 30 are connected by other springs (k1x and k4x) and the attenuators (c1x and c4x) arranged in the x-direction. Further, it is possible to perform modelling such that the bottom wafer 50 and the sensor frame 60 are connected by a spring (kdz) and an attenuator (cdz) arranged in the z-direction.

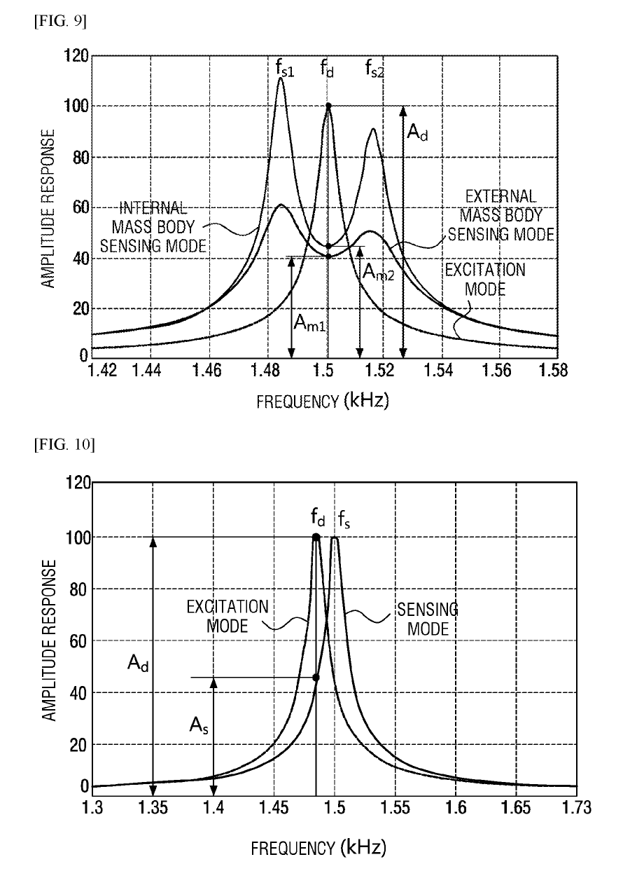

FIG. 9 illustrates a frequency response curve of an x-y axis gyroscope having the 1 degree of freedom vertical excitation mode and the 2 degrees of freedom horizontal sensing mode as in FIG. 8. Assuming that the x-direction displacement of the external mass body 30 is set as x1 on the basis of an equilibrium position with not external force, and the x-direction displacement of the internal mass body 40 is set as x2, the entire sensor mass bodies 30 and 40 have 2 degrees of freedom along the two independent parameters x1 and x2. At this time, the two parameters x1 and x2 have the same peak resonance frequency (fs1 and fs2). If the sensor mass bodies 30 and 40 of FIG. 8 are vertically excited with the maximum excitation amplitude (Ad) and the excitation frequency (fd), the external mass body 30 and the internal mass body 40 have a linear vibration movement with maximum amplitude (Am1) and maximum amplitude (Am2) by the Coriolis force (Fc) in the x-direction, respectively. Thus, the amplitude responses of the two mass bodies 30 and 40 have a relatively gentle slope between the two peak resonant frequencies. Therefore, even if the position of the excitation frequency slightly varies or even if the error due to the manufacturing process of the MEMS gyroscope, for example, the design error of the peak resonance frequency occurs, the sensing amplitude of each mass bodies 30 and 40 may fall within the stable range.

Compared with FIG. 9, considering the amplitude response of FIG. 10 having the sensing mode of 1 degree of freedom, the amplitude response of the sensing mode as well as the excitation mode have a steep slope. Therefore, even a small design error will result in a large change in the sensing amplitude. Therefore, as in the embodiment of FIG. 8, it is possible to provide more robust MEMS gyroscope to the manufacturing process errors by having the 2 degree of freedom sensing mode by the two mass bodies.

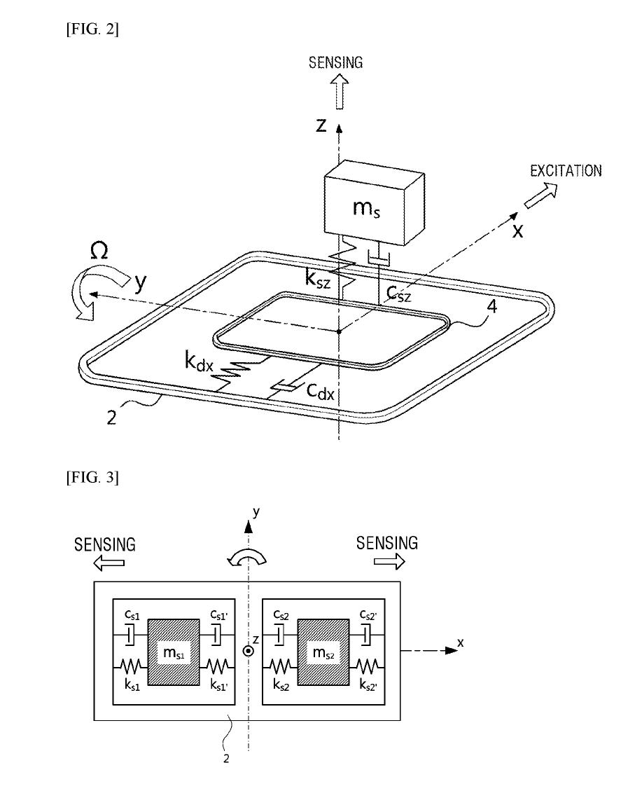

Referring again to FIG. 8, in the x-y axis gyroscope according to the embodiment of the present invention, the two mass bodies 30 and 40 are excited in the vertical direction (z-direction), and sensed in the horizontal direction (x-direction). As in the related art of FIG. 2, such a type can eliminate the problem of electrode placement which occurs when the mass bodies are excited in the horizontal direction and are sensed in the horizontal direction. In an embodiment, the present invention uses a seesaw type excitation to facilitate excitation in the vertical direction within a narrow spacing between the bottom wafer and the MEMS wafer (frame).

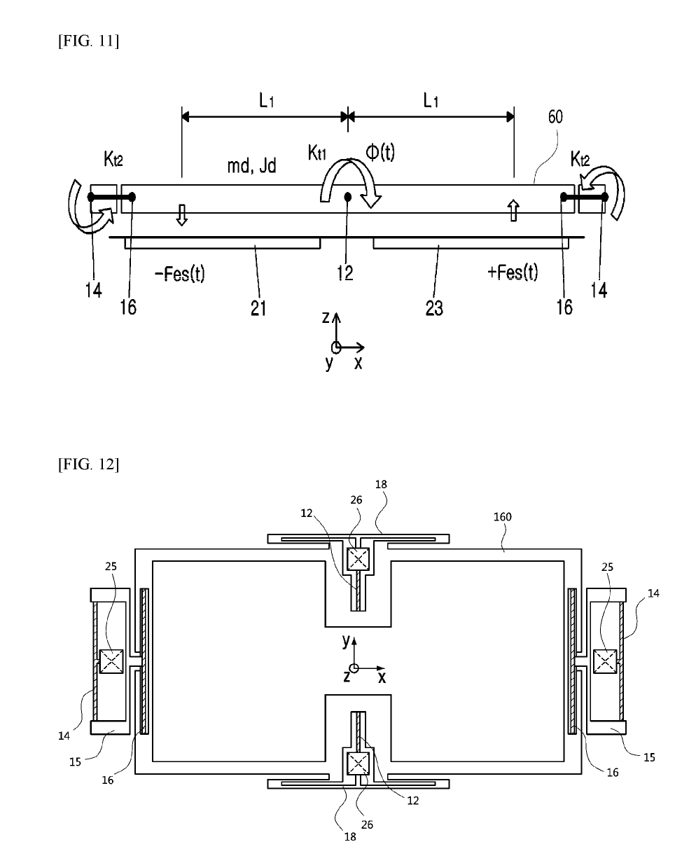

FIG. 11 illustrates the 1 degree of freedom mathematical model of the vertically excited gyro frame 60 and the torsional support springs 12, 14, and 16 in the x-y axis gyroscope according to an embodiment of the present invention. In FIG. 10, the frame 60 is excited in the seesaw type by the bottom electrode 21 and 23 so as to have the anti-phase vibration components in the vertical direction around the center position of the frame (the position of the torsional support spring 12). Therefore, if the excitation force is assumed as +Fes (t) at a point L1 away from the center of the frame 60 to the right side, the excitation force at the point L1 away from the center of the frame 60 to the left side becomes −Fes (t). Because of the excitation forces opposite to each other on the left and right sides, the Coriolis force according to the external rotational movement in the y-axis direction also has the anti-phase on the left and right sides.

FIG. 12 is a diagram schematically illustrating a frame 160, and support springs 12, 14, and 16 for connecting the frame 160 to the anchors 25 and 26 in the x-y axis gyroscope. In an embodiment, the frame 160 is allowed to twist around the y-axis by the two support springs 12 attached to the side walls of the two anchors 26. In the x-y plane, the support spring 14 causes a restoring torque to aid in restoring both edges of the frame 160 in the x-direction to their normal position after the torsional deformation of the frame 160.

The support spring 16 serves as a link or rotary bearing which connects the edge of the frame 160 and the support spring 14. Further, the flat panel link 15 is a kind of link that mechanically connects the support spring 14 and the support spring 16. A dummy beam spring 18 in the form of double folds of lateral and vertical symmetry are attached to both anchors 26 of the frame 160 to simultaneously suppress the bending deformation of the frame 160 in the Coriolis force direction (x) due to the support springs 12 and 14, and the rotational movement of the frame 160 to the vertical axis (z).

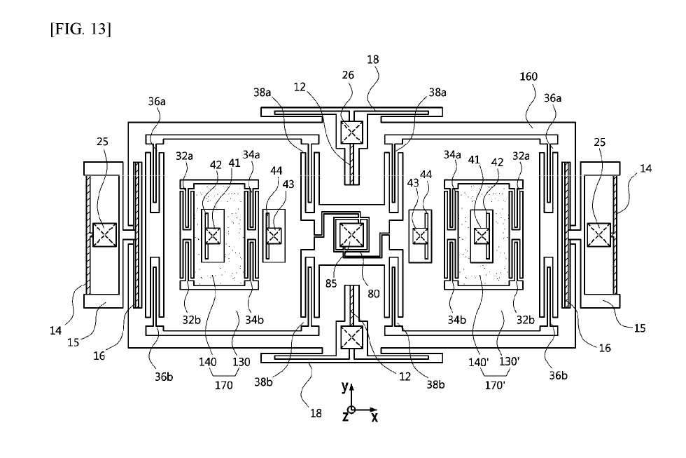

FIG. 13 illustrates the structure of the x-y axis gyroscope vertically excited and horizontally sensed on the x-y plane according to an embodiment of the invention. In an embodiment, the sensor mass body units 170 and 170′ are connected to the frame 160 in the x-axis direction by two pairs of support springs 36a, 36b, 38a, and 38b at positions spaced apart from each other by a certain distance on the left, right, up and down sides with respect to the y-axis at the center of the sensor mass body units 170 and 170′ to support linear vibration in the direction of Coriolis force (x). The sensor mass body units 170 and 170′ include external mass bodies 130 and 130′, and internal mass bodies 140 and 140′ surrounded by the external mass bodies 130 and 130′. Two pairs of support springs 32a, 32b, 34a, and 34b are also connected in the x-axis direction between the external mass bodies 130 and 130′ and the internal mass bodies 140 and 140′ at positions spaced part from each other by a certain distance on the left, right, up and down sides with respect to the y-axis. Therefore, the relative displacement in the x-axis direction may be generated between the external mass bodies 130 and 130′ and the frame 160, and between the internal mass bodies 140 and 140′ and the external mass bodies 130 and 130′.

The operation of the sensor mass body units 170 and 170′ in the direction (x) of Coriolis force may be sensed by the interval between the respective sensor mass bodies 170 and 170′ or a change in the electrostatic capacity according to the area variation. In particular, the sensing electrode 42 is provided for sensing vibration in the x-direction of internal mass bodies 140 and 140′ of the sensor mass body units 170 and 170′, and the sensing electrode 43 is provided for detecting the vibration in the x-direction of the external mass bodies 130 and 130′ of the sensor mass body units 170 and 170′. Each of the sensing electrodes 42 and 44 may be provided as a comb electrode or a plate electrode, and may be attached to the side surfaces of the anchors 41 and 43 fixed to the wafer substrate, respectively.

In particular, in the embodiment of FIG. 13, the two mass body units are connected to the other end of the anti-phase link mechanism 80 which is fixed to the anchor 85 at one end. As described above, in the present invention, two mass body units are disposed in the x-axis direction so that the anti-phase is provided between the two mass body units. Such an anti-phase is basically provided by the vertical anti-phase excitation according to the seesaw mechanism as illustrated in FIG. 11. In this way, if the movement of the sensor mass body also has a structural symmetry together with the structural symmetry of the MEMS gyroscope, there is an advantage that the noise components generated for various reasons are offset by the symmetry, the perfect anti-phase movement of the sensor mass body unit is one of the goals that should be sought in fabricating the MEMS gyroscope.

Therefore, in order to ensure that the two sensor mass bodies 170 and 170′ have the perfect anti-phase movement in the sensing mode, in the embodiment of FIG. 13, the two sensor mass bodies 170 and 170′ are connected to the anti-phase link mechanism 80 disposed near the center of the frame 160. In the anti-phase link mechanism 80, due to the structural characteristics (rotationally symmetrical structure), if a force is applied to one arm of the two link arms in any direction, force in the direction exactly opposite to the applied force, that is, the anti-phase force acts on the other arm.

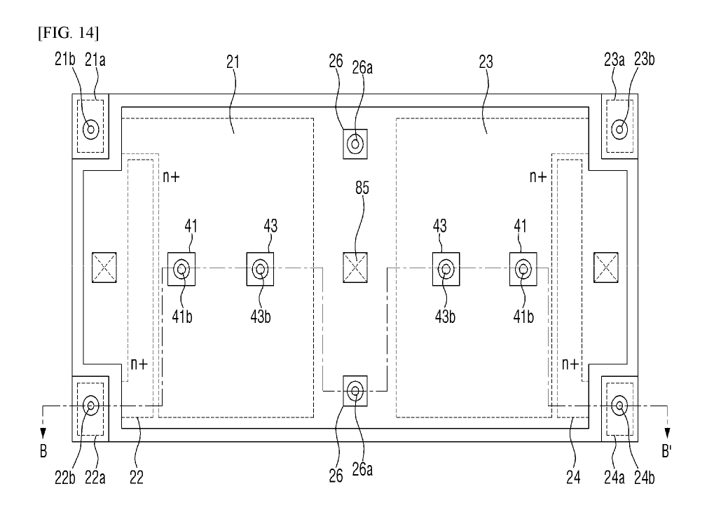

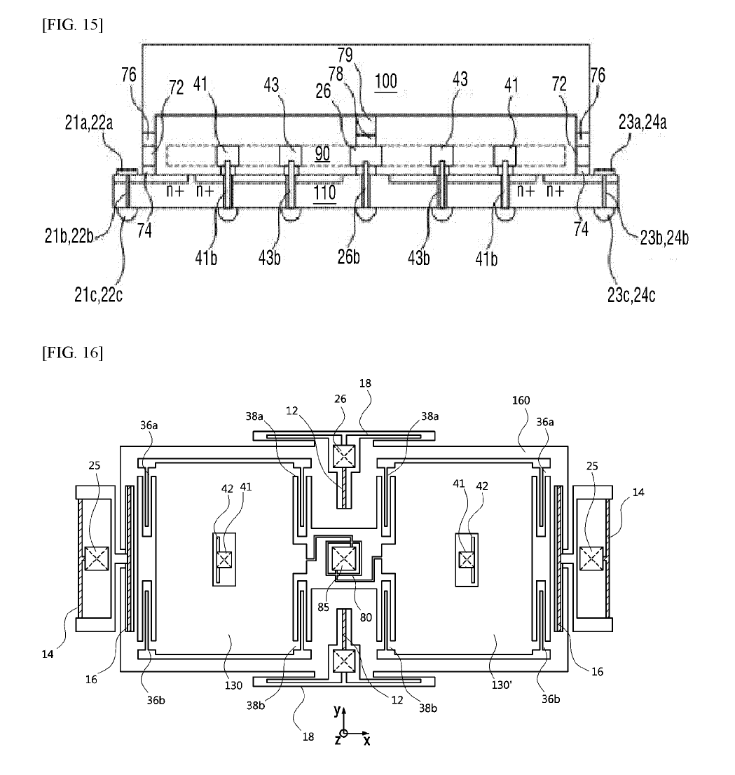

FIG. 14 is a plan view schematically illustrating the n or p-electrodes 21, 22, 23, and 24 on the front surface of the bottom wafer, the dummy metal pads 21a, 22a, 23a, and 24a on the front surface of the bottom wafer, the silicon penetration electrodes 21b, 22b, 23b, 24b, 41b, and 43b of the bottom wafer, and the sealing wall 72. FIG. 15 is a diagram schematically illustrating a cross section taken along the line B-B′ of the x-y axis gyroscope of FIG. 14.

In FIGS. 14 and 15, the sealing walls 72, 74, and 76 are one wall which shuts off the inside and the outside for the vacuum sealing of the x-y axis gyroscope. The bottom electrodes 21 and 23 are the n or p-doping electrodes intended for the vertical excitation of the frames 60 and 160 doped with boron or phosphorous on the wafer substrate, and the bottom electrode 22 and 24 are the n or p-doping electrodes for measuring the interval variation of the frames 60 and 160 in the vertical direction. The silicon penetration electrode 26b of the bottom wafer 110 means a wiring connection for supplying power to the frames 60 and 160 and the sensor mass bodies 170 and 170′, and the silicon penetration electrodes 41b and 43b of the bottom wafer 110 are wirings which output the signals sensed by the sensor sensing electrodes 41a and 43a to the outside. Further, the silicon penetration electrodes 21b and 23b of the bottom wafer are wirings that supply power to the bottom electrodes 21 and 23, and the silicon penetration electrodes 22b and 24b are wirings that sense the signals of the bottom electrodes 22 and 24.

The dummy metal pads 21a, 22a, 23a, and 24a are metal pads deposited on the doping electrodes 21, 22, 23, and 24 connected to the outside of the sealing wall by the conductive metal, and serve to electrically connect the silicon penetration electrodes 21b, 22b, 23b, and 24b and the doping electrodes 21, 22, 23, and 24. Pillars 78 and 79 are provided between the cap wafer 100 and the gyro wafer 90, and the excitation vibration energy of the frames 60 and 160 may be dividedly dispersed to the bottom wafer 110 and the cap wafer 100, respectively.

In the above description, an example in which the anti-phase link mechanism 80 is applied to the x-y axis MEMS gyroscope having the 1 degree of freedom excitation mode and 2 degrees of freedom sensing mode has been specifically described. However, the anti-phase link mechanism 80 is not necessarily applied to the MEMS gyroscope having such 2 degrees of freedom sensing mode. As long as the symmetrical structure between the two mass body units is maintained (tuning fork type), it is a matter of course that the anti-phase link mechanism 80 is also applicable to the x-y axis MEMS gyroscope having the 1 degree of freedom excitation mode and 1 degree of freedom sensing mode as in FIG. 4. Assuming the 1 degree of freedom sensing mode, the internal mass body is removed from the x-y type MEMS gyroscope of FIG. 13, and may be configured as in FIG. 16.

On the other hand, the anti-phase link mechanism 80 according to an embodiment of the present invention is applicable to the x-y axis MEMS gyroscope as described above, and is also applicable to the z-axis MEMS gyroscope. Hereinafter, a specific embodiment will be described in which the anti-phase link mechanism 80 is applied to the z-axis MEMS gyroscope.

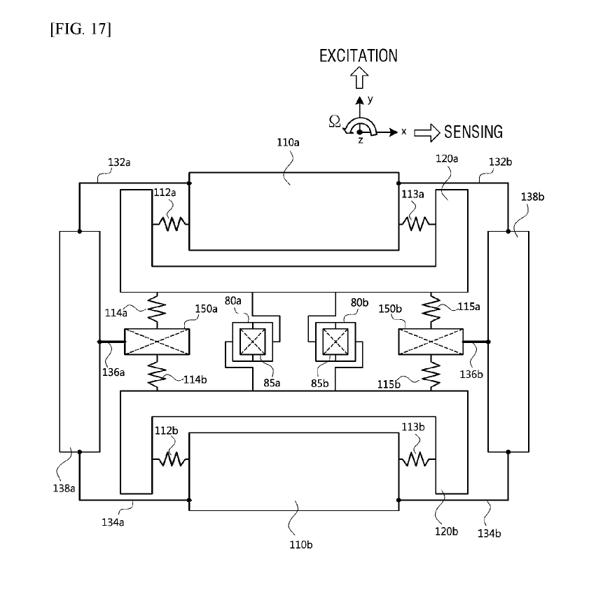

Referring to FIG. 17, if the sensor mass bodies 110a and 110b and the sensor frames 120a and 120b are excited in the y-direction under the condition that the rotation in the z-axis direction is applied to the gyro wafer, the sensor mass bodies 110a and 110b move in the x-axis direction by the Coriolis force. Here, the sensor mass bodies 110a and 110b include a first sensor mass body unit 110a and a second sensor mass body unit 110b, and the sensor frames 120a and 120b may be configured to include a first sensor frame unit 120a and a second sensor frame unit 120b. The sensor mass bodies 110a and 110b are connected to the sensor frames 120a and 120b by the support springs 112a, 113a, 112b, and 13b disposed in the horizontal direction, respectively. Therefore, the sensor mass bodies 110a and 110b may have a relative displacement in the x-direction with respect to the sensor frames 120a and 120b.

Further, the support springs 114a, 114b, 115a, and 115b for supporting the movement of the sensor mass bodies 110a and 110b and the sensor frames 120a and 120b in the y-direction are connected between the anchors 150a and 150b and the sensor frames 120a and 120b in the y-direction. At least one or more anti-phase link mechanisms 80a and 80b are connected between the two sensor frames 120a and 120b, in order to ensure the perfect anti-phase of the movement of the sensor frames 120a and 120b in the y-direction in the excitation mode. Although a pair of two anti-phase link mechanisms 80a and 80b is disposed in FIG. 17, the number thereof is not limited thereto. However, from the viewpoint of eliminating the effect of the unbalance of the disposition of the anti-phase link mechanism, it is preferable to use a plurality of anti-phase link mechanisms, in particular, it is necessary to dispose the plurality of anti-phase link mechanisms so as to be axisymmetrical in the left-right direction on the basis of the center.

Meanwhile, in an embodiment of the present invention, in order to guide the first sensor mass body unit 110a and the second sensor mass body unit 110b to move in the opposite directions to each other on the basis of the x-axis at the time of the sensing mode, at least two horizontal seesaw link structures (138a, 132a, 134a, and 136a or 138b, 132b, 134b, and 136b) may be used. At this time, the horizontal seesaw link structure may be configured to include seesaw main bodies 138a and 138b, rotary links 132a, 132b, 134a, and 134b for connecting both ends of the seesaw main bodies 138a and 138b to the sensor mass bodies 110a and 110b, and pivot links 136a and 136b for connecting the centers of the seesaw body 138a and 138b with the fixing anchors 150a and 150b.

For example, if the first sensor mass body unit 110a moves in the positive x-axis direction (rightward direction), the upper rotary links 132a and 132b also move in the positive x-axis direction to provide the movement in which the seesaw bodies 138a and 138b pivot in the clockwise direction. At this time, since the lower ends of the seesaw bodies 138a and 138b move in the negative x-axis direction (leftward direction) due to the central pivot links 136a and 136b, the lower rotary links 134a and 134b move to the left side. Finally, the movement of the second sensor mass body unit 110b is guided in the negative x-axis direction (leftward direction) opposite to the direction of the first sensor mass body unit 110a.

FIG. 18 is a diagram illustrating the anti-phase link mechanism 180a according to an embodiment of the present invention. In this embodiment, the two link arms 141a and 142a and the torsional stiffness support part 147a of the anti-phase link mechanism 180a have the same structure as compared with that of the anti-phase link mechanism of FIG. 7. Instead, in this embodiment, four central anchors 145a are used. Also, the method of connecting the torsional stiffness support part 147a and the four central anchors 145a has a substantially ‘I-beam’ shape. Specifically, the torsional stiffness support part 147a is connected by a horizontal link 144a crossing the same, and the center of the horizontal link 144a is connected to the I-beam link 143a connected to the four central anchors 145a. Due to the structure connected to these four central anchors 145a in the I-beam shape, the anti-phase link mechanism 180a may have a relatively large stiffness with respect to the torsional external force.

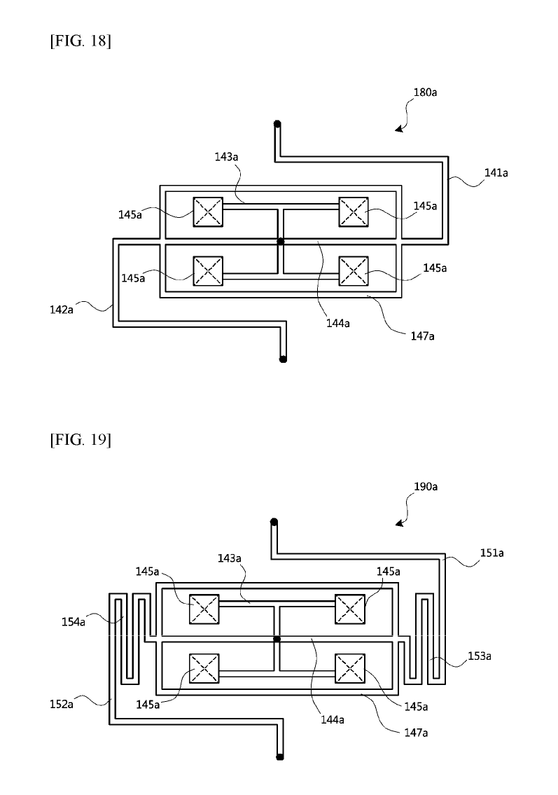

FIG. 19 is a diagram illustrating an anti-phase link mechanism 190a according to another embodiment of the present invention. In this embodiment, as compared with FIG. 18, there is only a difference in that spring portions 153a and 154a are additionally formed in the two link arms 151a and 152b. When the external force (+F or −F) acts on the end portions of the link arms 151a and 152b, the spring portions 153a and 154a formed on the link arms 151a and 152b enhance stiffness of the two link arms 151a and 152b to a certain degree, and provide the structural stability of the two link arms 151a and 152b. Therefore, it is possible to contribute to ensuring a more accurate anti-phase as compared with the case where the spring portions 153a and 154a do not exist.

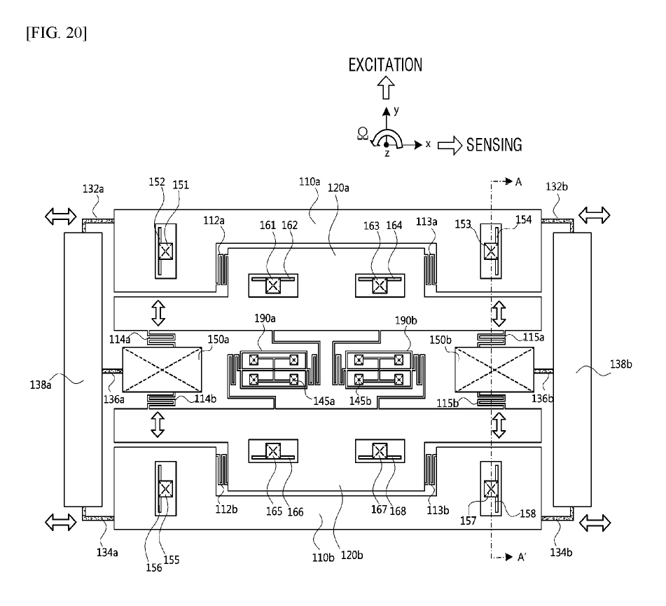

FIG. 20 illustrates the z-axis gyroscope structure horizontally excited and horizontally sensed on the x-y plane according to an embodiment of the present invention. A pair of anti-phase link mechanisms 190a and 190b of FIG. 19 is disposed as an example here.

Under the condition that the rotational angular velocity ω in the z-axis direction is applied onto the gyro wafer, the sensor mass bodies 110a and 110b and the sensor frames 120a and 120b are excited together in the y-direction by the excitation electrodes 162, 164, 166, and 168. The excitation electrodes 162, 164, 166, and 168 may be provided as a comb electrode, a plate electrode or other types. The excitation electrodes 162, 164, 166, and 168 are attached and fixed to the side surfaces of the anchors 161, 163, 165, and 167 fixed to the wafer substrate, respectively. In the embodiment of FIG. 20, the case of using the four excitation electrodes is taken as an example, but the invention is not limited thereto, and it goes without saying that smaller or larger number of excitation electrodes than this case may be used.

In the above-mentioned excitation mode, the relative displacement of the sensor mass bodies 110a and 110b and the sensor frames 120a and 120b do not substantially occur in the y-direction, and the vibration according to the excitation is supported by the support springs 114a, 114b, 115a, and 115b disposed in the vertical direction (y-direction). At this time, the two sensor frames 120a and 120b are connected in the y-direction by the two anti-phase link mechanisms 190a and 190b.

The two anti-phase link mechanisms 190a and 190b are disposed symmetrically (axial-symmetrically) with respect to each other in the x-axis direction. In the anti-phase link mechanism 190a and 190b, the force acting on the end portion of the link arm is converted into reactive force of the perfectly opposed phase at the end portion of the other link arm due to the rotationally symmetric structure of the anti-phase link mechanism 190a and 190b. Therefore, when the first sensor frame unit 120a moves downward, the lower link arms of the anti-phase link mechanisms 190a and 190b pull the second sensor frame unit 120b upward. Conversely, when the first sensor frame unit 120a moves upward, the lower link arms of the anti-phase link mechanisms 190a and 190b push the second sensor frame unit 120b downward. Accordingly, by the excitation electrodes 162, 164, 166, and 168, even if the excitation force applied to the upper first sensor mass body unit 110a and the first sensor frame unit 120a, and the excitation force applied to the lower second sensor mass body unit 110b and the second sensor frame unit 120b do not have the perfect anti-phase, the perfect anti-phase by the anti-phase link mechanisms 190a and 190b may be actually ensured in the vibration of the sensor mass bodies 110a and 110b and the sensor frames 120a and 120b.

On the other hand, when the rotation angular velocity ω in the z-axis direction and the excitation in the y-axis direction simultaneously act, the sensor mass bodies 110a and 110b vibrate in the x-direction due to the Coriolis force. Here, the sensor mass bodies 110a and 110b are connected to the sensor frames 120a and 120b by the support springs 112a, 113a, 112b, and 113b arranged in the horizontal direction, respectively. These support springs 112a, 113a, 112b, and 113b may also be provided as a MEMS beam spring of a folding type capable of being linearly deformed. Therefore, in the sensing mode, the sensor frames 120a and 120b do not substantially move in the x-direction, and the sensor mass bodies 110a and 110b do not move in the x-direction with respect to the sensor frames 120a and 120b.

On the other hand, the excitation directions of the two sensor mass bodies 110a and 110b are ensured to have the perfect anti-phase with respect to the y-axis by the anti-phase link mechanisms 190a and 190b at the time of excitation. Thus, the Coriolis force acting on the two sensor mass bodies 110a and 110b is also perfectly opposite. Therefore, in the sensing mode, when the first sensor mass body unit 110a move in the negative x-axis direction (leftward direction), the second sensor mass body unit 110b moves in the positive x-axis direction (rightward direction). Further, when the first sensor mass body unit 110a moves in the positive x-axis direction (rightward direction), the second sensor mass body unit 110b moves in the negative x-axis direction (leftward direction). The opposite movement of the sensor mass bodies 110a and 110b in the sensing mode is naturally guided by the horizontal seesaw link structures (138a, 132a, 134a, and 136a or 138b, 132b, 134b, and 136b). The horizontal seesaw link structure includes seesaw bodies 138a and 138b, rotary links 132a, 132b, 134a, and 134b which connect both ends of the seesaw bodies 138a and 138b to each of the sensor mass bodies 110a and 110b, and pivot links 136a and 136b which connect the centers of the seesaw bodies 138a and 138b to the fixing anchors 190a and 190b. Therefore, when the first sensor mass body unit 110a moves in the x-axis direction (rightward direction), the upper rotary links 132a and 132b also move in the x-axis direction to provide a movement in which the upper seesaw bodies 138a and 138b pivot in the clockwise direction. At this time, the lower ends of the seesaw bodies 138a and 138b move in the negative x-axis direction (leftward direction) by the center pivot links 136a and 136b, and thus, the lower rotary links 134a and 134b move to the left side. Finally, the movement of the second sensor mass body unit 110b is guided in the negative x-axis direction (leftward direction) opposite to that of the first sensor mass body unit 110a.

The movement of the sensor mass bodies 110a and 110b in the direction of Coriolis force (x-direction) may be sensed by the interval between each of the sensor mass bodies 110a and 110b and each of the sensing electrodes 152, 154, 156, and 158, or a change in electrostatic capacitance due to the area variation. These sensing electrodes 152, 154, 156, and 158 may also be provided as comb electrodes or plate electrodes, and may be attached to the side surfaces of the anchors 151, 153, 155, and 157 fixed to the wafer substrate, respectively. In the embodiment of FIG. 20, the case of using the four sensing electrodes is taken as an example, but the present invention is not limited thereto, and it goes without saying that the smaller or larger number of sensing electrodes than this case may be used.

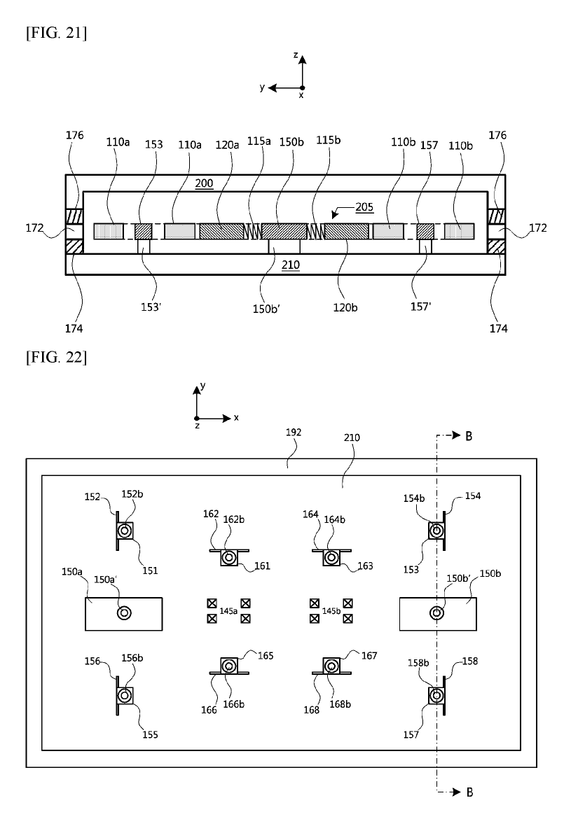

FIG. 21 is a diagram schematically illustrating a cross section taken along line A-A′ of the z-axis MEMS gyroscope of FIG. 20. In FIG. 21, the z-axis MEMS gyroscope of FIG. 20 is located in the internal space between the bottom wafer 210 and the cap wafer 200 surrounded by the sealing walls 172, 174, and 176 of the gyro wafer 205. The support springs 115a and 115b connect the anchor 150b and the sensor frames 120a and 120b, and serve as a support when the sensor frames 120a and 120b are excited in the y-axis direction.

Anchors 153 and 157 for fixing the sensing electrodes are located inside the sensor mass bodies 110a and 110b, and the bottom wafer 210 is disposed to be spaced at a regular interval below the sensor frames 120a and 120b and the sensor mass bodies 110a and 110b, that is, below the gyro wafer 205. At this time, the anchors 150b, 153, and 157 extend to abut on the bottom wafer 210 from the gyro wafer 205 (150b′, 153′, and 157′). Therefore, even when the sensor frames 120a and 120b or the sensor mass bodies 110a and 110b in the gyro wafer 205 vibrate, the anchors 150b, 153, and 157 are fixed without movement.

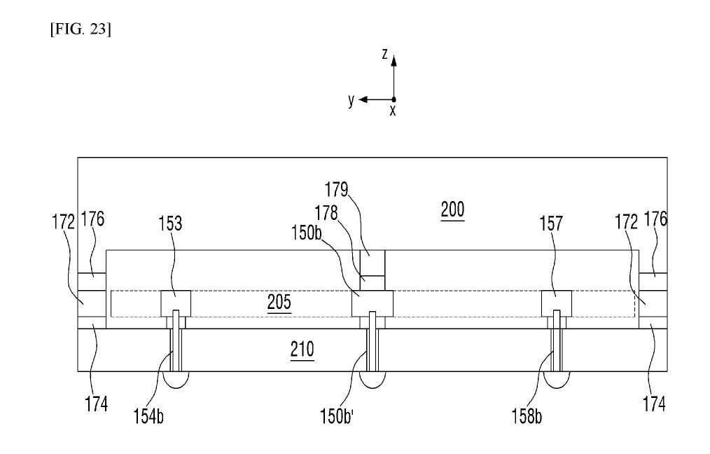

FIG. 22 is a plan view illustrating, in the z-axis gyroscope according to the embodiment of FIG. 20, various anchors (150a, 150b, 151, 153, 155, 157, 161, 163, 165, 167, 145a, and 145b), the silicon penetration electrodes (150a′, 150b′, 152b, 154b, 156b, 158b, 162a, 164b, 166b, and 168b) of the bottom wafer 210, and the sealing wall 192. Further, FIG. 23 is a diagram schematically illustrating a cross section taken along the line B-B′ from the x-y axis gyroscope of FIG. 22.

In FIG. 23, the sealing walls 172, 174, and 176 are one wall that shuts off the inside and the outside in order to protect the structure of the z-axis gyroscope. The silicon penetration electrode 150b′ of the bottom wafer 210 means a wiring connection which supplies power to the sensor frames 120a and 120b and the sensor mass bodies 110a and 110b, and the silicon penetration electrodes 154b and 158b are wirings which output the signals sensed by the sensor sensing electrodes 154 and 158 to the outside. Further, pillars 178 and 179 are provided between the cap wafer 200 and the gyro wafer 205, such that vibration energy of the gyro wafer 205 can be dividedly dispersed to the bottom wafer 210 and the cap wafer 200, respectively.

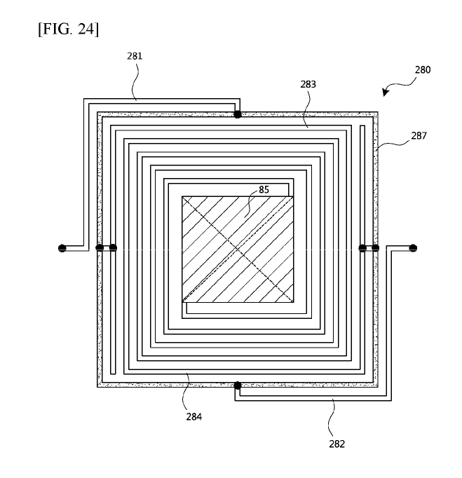

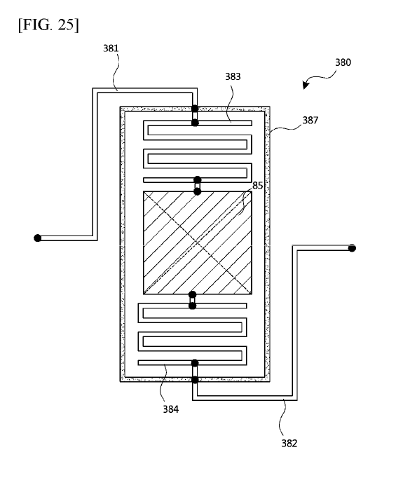

In the above description, the embodiment in which the anti-phase link mechanism 80 used in the x-y axis MEMS gyroscope, and the anti-phase link mechanisms (80a, 80b, 180a, 180b, 190a, and 190b) used in the z-axis MEMS gyroscope are applied has been specifically described. The invention is not limited thereto, and other embodiments capable of being replaced with the anti-phase link mechanisms (80a, 80b, 180a, 180b, 190a, and 190b) are illustrated in the following FIGS. 24 to 27. In the explanation of FIGS. 24 to 27, the horizontal direction means a direction in which the two mass bodies are disposed, and the vertical direction means a direction perpendicular to the horizontal direction.

The anti-phase link mechanism 280 illustrated in FIG. 24 is basically similar to the anti-phase link mechanism 80 illustrated in FIG. 7, and the configurations of the closed curve torsional stiffness support part 287 and the two link arms 281 and 282 are the same. However, there is a difference in that helical anchor connecting parts 283 and 284 repeated several times to enhance the stiffness of the two anchor connecting parts 83 and 84 are replaced. In order to stably operate the anti-phase link mechanism 280, it is basically necessary to firmly fix the anti-phase link mechanism 280 to the anchor 85. However, due to the structural constraint of the MEMS gyroscope, it is difficult to increase the thickness of the anchor connecting parts 283 and 284. Thus, when using the helical anchor connecting parts 283 and 284 repeated several times in this way, there is an advantage capable of dispersing the torsional stress applied to the portion connected with the anchor.

On the other hand, an anti-phase link mechanism 380 according to another embodiment of the present invention illustrated in FIG. 25 differs from the anti-phase link mechanism 80 illustrated in FIG. 7 in that two anchor connecting parts 383 and 384 have a shape repeatedly folded along one side of the torsional stiffness support part 87 (a shape repeatedly folded in the vertical direction). Such an anti-phase link mechanism 380 provides considerable resistance (high stiffness) against the movement of the mass bodies disposed on the left and right sides in the same direction.

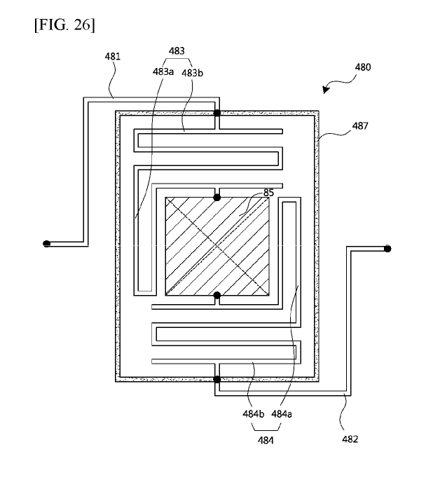

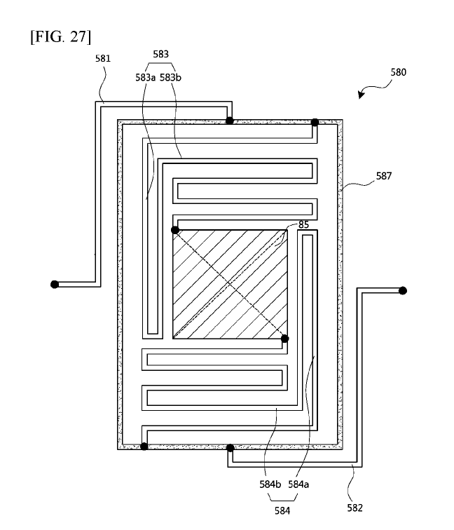

An anti-phase link mechanism 480 according to still another embodiment of the present invention illustrated in FIG. 26 differs from the anti-phase link mechanism 80 illustrated in FIG. 7 in that each of the two anchor connecting parts 483 and 484 is configured to include first folding parts 483a and 484a starting from a point connected to the central anchor 85 and folded in the horizontal direction, and second folding parts 483b and 484b connected to the first folding parts 483a and 484a and having a shape folded in the vertical direction.

On the other hand, the anti-phase link mechanism 580 according to still another embodiment of the present invention illustrated in FIG. 27 has both of a part folded in the horizontal direction and a part folded in the vertical direction, as in the anti-phase link mechanism 480 illustrated in FIG. 26. The connection order from the central anchor 85 is only reversed in that the portion connected to the central anchor 85 is a part folded in the vertical direction. Thus, in the anti-phase link mechanism 580, each of the two anchor connecting parts 583 and 584 is configured to include first folding parts 583b and 584b starting from the point connected to the central anchor 85 and folded in the vertical direction, and second folding parts 583a and 584a connected to the first folding parts 583b and 584b and having a shape folded in the horizontal direction.

Since the anti-phase link mechanisms 480 and 580 described in FIGS. 26 and 27 include both the part folded in the horizontal direction and the part folded in the vertical direction portion starting from the central anchor 85, there is an advantage capable of adjusting the frequency in the direction of rotation and the frequency of movement in the linear direction.

While the embodiments of the present invention have been described with reference to the accompanying drawings, those skilled in the art to which this invention pertains will appreciate that the invention can be implemented in other specific forms without changing the technical sprit or the essential features. Accordingly, it is understood that the embodiments described above are illustrative in all aspects and are not limiting.

What is claimed is:

1. A MEMS anti-phase link mechanism for ensuring anti-phase movements of two axisymmetric mass body units forming a sensor mass body, in a MEMS-based gyroscope comprising: a frame disposed to be parallel to a bottom wafer substrate; the sensor mass body in which displacement is sensed by Coriolis force when a movement in an excitation direction and an external angular velocity are input to the frame; and at least one sensing electrode which senses the displacement of the sensor mass body, the MEMS anti-phase link mechanism comprising:
at least two anchor connecting parts connected to an immovable central anchor; and
at least two link arms which are connected to the at least two anchor connecting parts, and are connected to the two mass body units in a 180-degree rotational symmetry with each other on the basis of the center of the MEMS anti-phase link mechanism.

2. The MEMS anti-phase link mechanism of claim 1, wherein the at least two anchor connecting parts are connected to the central anchor in a 180-degree rotational symmetry with each other on the basis of the center of the MEMS anti-phase link mechanism.

3. The MEMS anti-phase link mechanism of claim 1, further comprising:
a torsional stiffness support part formed by a closed curve, while passing through a point on which the at least two anchor connecting parts meet the at least two link arms in order to impart torsional stiffness of the MEMS anti-phase link mechanism.

4. The MEMS anti-phase link mechanism of claim 3, wherein the torsional stiffness support part has a rectangular shape.

5. The MEMS anti-phase link mechanism of claim 4, wherein the at least two link arms has at least three bending points (cusps) from a point connected to the torsional stiffness support part to a point connected to the two mass body units.

6. The MEMS anti-phase link mechanism of claim 5, wherein the at least two link arms comprise a first art extending in a first direction parallel to one side of the torsional stiffness support part, a second arm extending in a second direction perpendicular to the first direction from a distal end of the first arm, a third arm extending from a distal end of the second arm in a direction opposite to the first arm, and a fourth arm extending in the second direction from a distal end of the third arm.

7. The MEMS anti-phase link mechanism of claim 4, wherein the central anchor comprises four anchors, the at least two anchor connecting parts meet the four anchors at four points, and a shape in which the anchor connecting parts are connected to the four anchors from the center of the MEMS anti-phase link mechanism is a substantially ‘I’ shape.

8. The MEMS anti-phase link mechanism of claim 4, wherein each of the at least two anchor connecting parts is connected to the torsional stiffness support part in a square spiral shape repeated at the central anchor.

9. The MEMS anti-phase link mechanism of claim 8, wherein the two points at which the at least two anchor connecting parts are connected to the central anchor are positions of opposing apexes of the central anchor.

10. The MEMS anti-phase link mechanism of claim 4, wherein each of the at least two anchor connecting parts comprises a first folding portion having a shape that is repeatedly folded along one side of the torsional stiffness support part.

11. The MEMS anti-phase link mechanism of claim 10, wherein each of the at least two anchor connecting parts further comprises a second folding part which is formed near the point connected to the central anchor, is connected to the first folding part, and has a shape folded in a direction perpendicular to the first folding part.

12. The MEMS anti-phase link mechanism of claim 10, wherein each of the at least two anchor connecting parts further comprises a second folding part which is connected to the first folding part connected to the central anchor, and has a shape folded in the direction perpendicular to the first folding part.
